(19) United States
(12) Patent Application Publication
(10) Pub. No.: US 2025/0331297 A1
(43) Pub. Date: Oct. 23, 2025

(54) A DOUBLE-CHANNEL SEMICONDUCTOR DEVICE

(71) Applicant: Power Integrations, Inc., San Jose, CA (US)

(72) Inventors: Alexey KUDYMOV, Ringoes, NJ (US); Brian Harold FLOYD, Sunnyvale, CA (US); Jamal RAMDANI, Lambertville, NJ (US)

(73) Assignee: Power Integrations, Inc., San Jose, CA (US)

(21) Appl. No.: 18/868,383

(22) PCT Filed: Jun. 15, 2022
(86) PCT No.: PCT/US2022/033543

§ 371 Date: Nov. 22, 2024

(51) Int. Cl. H10D 84/84; H10D 84/01

(52) U.S. Cl. CPC H10D 84/84; H10D 84/0163

(57) ABSTRACT

A double-channel semiconductor device is presented herein. The double-channel semiconductor device is a cascode solution integrating two semiconductor channels: a HEMT channel (104) and a thin film transistor (TFT) channel (216). The HEMT channel can be an AIGaN/GaN HEMT channel and the TFT channel can be a polycrystalline silicon (polysilicon) TFT channel. The polysilicon TFT may advantageously operate in enhancement mode to realize an enhancement-mode cascode device.

### FIELD OF THE DISCLOSURE

The present invention relates to a double-channel semiconductor device and more particularly to a cascode semiconductor device including a thin film transistor.

### BACKGROUND INFORMATION

Gallium nitride (GaN) and other wide band-gap nitride III based direct transitional semiconductor materials exhibit high break-down electric fields and avail high current densities. In this regard GaN based semiconductor devices are actively researched as an alternative to silicon based semiconductor devices in power and high frequency applications. For instance, a GaN high electron mobility transistor (HEMT) may provide lower specific on resistance with higher breakdown voltage relative to a silicon power field effect transistor of commensurate area.

Thin film transistors (TFTs) can be made of polycrystalline silicon, amorphous silicon, organic and metal oxide. The mobility depends on its crystalline morphology and structural disorders which give rise to scattering events. Carrier mobility in polycrystalline silicon TFTs can reach up to one hundred centimeter squared per volt second.

Thin-film transistors typically include a source, drain and gate. A dielectric layer separates a gate electrode from an active semiconducting film, whereas source and drain contacts are directly connected to the semiconductor. As a voltage is applied to the gate electrode, the majority charge carriers are attracted by the electric field and form a conducting channel.

### BRIEF DESCRIPTION OF THE DRAWINGS

Non-limiting and non-exhaustive embodiments for a double-channel semiconductor device are described with reference to the following figures, wherein like reference numerals refer to like parts throughout the various views unless otherwise specified.

FIG. 1A illustrates a cross section of a double-channel semiconductor device according to a first embodiment.

FIG. 1B illustrates the thin film transistor and the high electron mobility transistor of the first embodiment.

FIG. 2A illustrates a cross section of a double-channel semiconductor device according to a second embodiment.

FIG. 2B illustrates the thin film transistor and the high electron mobility transistor of the second embodiment.

FIG. 3A illustrates a cross section of a double-channel semiconductor device according to a third embodiment.

FIG. 3B illustrates the thin film transistor and the high electron mobility transistor of the third embodiment.

FIG. 4 illustrates process flow steps for fabricating a double-channel semiconductor device according to a first embodiment.

FIG. 5A illustrates process flow steps for fabricating a double-channel semiconductor device according to a second embodiment.

FIG. 5B illustrates additional process flow steps for fabricating a double-channel semiconductor device according to the second embodiment.

FIG. 6 illustrates a schematic diagram of a double-channel semiconductor device including a HEMT and TFT according to an embodiment.

FIG. 7 illustrates a device structure realization of the thin film transistor and the high electron mobility transistor according to a simulated embodiment.

FIG. 8 illustrates a device structure of the thin film transistor according to a first double-channel embodiment.

FIG. 9 illustrates simulated drain current versus applied gate voltage according to the first double-channel embodiment.

FIG. 10 illustrates simulated characteristic curves according to the first double-channel embodiment.

FIG. 11 illustrates simulated switching waveforms according to the first double-channel embodiment.

FIG. 12 illustrates a device structure of the thin film transistor according to a second double-channel embodiment.

FIG. 13 illustrates simulated electric field of the thin film transistor according to the second double-channel embodiment.

FIG. 14 illustrates simulated characteristic curves according to the second double-channel embodiment.

FIG. 15A compares simulated off-state current according to thin film transistor embodiments.

FIG. 15B illustrates simulated electric field of the thin transistor according to an embodiment.

FIG. 15C illustrates simulated electric field of the thin transistor according to another embodiment.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements and layers in the figures may be exaggerated relative to other elements to help to improve understanding of various embodiments of the teachings herein. Also, common but well-understood elements, layers, and/or process steps that are useful or necessary in a commercially feasible embodiment are often not depicted in order to facilitate a less obstructed view of these various embodiments of a double-channel semiconductor device.

### DETAILED DESCRIPTION

In the following description, numerous specific details are set forth in order to provide a thorough understanding of a double-channel semiconductor device. It will be apparent, however, to one having ordinary skill in the art that the specific detail need not be employed to practice the teachings herein. In other instances, well-known materials or methods have not been described in detail in order to avoid obscuring the present disclosure.

Reference throughout this specification to “one embodiment”, “an embodiment”, “one example” or “an example” means that a particular feature, structure, method, process, and/or characteristic described in connection with the embodiment or example is included in at least one embodiment of a double-channel semiconductor device. Thus, appearances of the phrases “in one embodiment”, “in an embodiment”, “one example” or “an example” in various places throughout this specification are not necessarily all referring to the same embodiment or example. Furthermore, the particular features, structures, methods, processes and/or characteristics may be combined in any suitable combinations and/or subcombinations in one or more embodiments or examples. In addition, it is appreciated that the figures provided herewith are for explanation purposes to persons ordinarily skilled in the art and that the drawings are not necessarily drawn to scale.

In the context of the present application, when a transistor is in an “off-state” or “off” the transistor blocks current and/or does not substantially conduct current. Conversely, when a transistor is in an “on-state” or “on” the transistor is able to substantially conduct current. By way of example, a transistor may comprise an N-channel metal-oxide-semiconductor (NMOS) field-effect transistor (FET) with the high-voltage being supported between the first terminal, a drain, and the second terminal, a source.

Also, throughout this specification, several terms of art are used. These terms are to take on their ordinary meaning in the art from which they come, unless specifically defined herein or the context of their use would clearly suggest otherwise. For instance, one of ordinary skill in the art may recognize and distinguish sheet resistance (i.e., sheet rho) from resistivity. Additionally, it should be noted that element names and symbols may be used interchangeably throughout this document (e.g., Si vs. silicon); however, both have identical meanings.

As discussed herein an enhancement mode device may refer to a transistor which has a threshold voltage greater than zero while a depletion mode device may refer to a transistor which has a threshold voltage less than zero. In many circuit and switching applications, it may be desirable to use an enhancement mode transistor (i.e., an enhancement mode device) to realize circuit functions. For instance, in power applications it is often desirable to use a power transistor as a switch (i.e., a power switch). Ideally, a power transistor may operate as a switch when it blocks current in one state (e.g., a state of zero control voltage) and provides current with low on resistance and low power loss in a second state (e.g., a state of non-zero control voltage).

Nitride based high electron mobility transistors (HEMTs) are naturally normally-on devices (i.e., depletion-mode devices), whereby a channel conducts current when zero gate bias is applied and whereby the off-state is achieved with application of negative gate bias. This complicates their adoption in power electronics where for safety reasons, normally-off operation is preferred. Accordingly, there is a need for a HEMT which can operate with normally-off operation (i.e., enhancement mode operation).

Present state of the art enhancement mode GaN HEMTs include p-GaN HEMTs and recessed gate metal insulator semiconductor HEMTs (MISHEMTs). A p-GaN HEMT may be fabricated by providing a p-GaN layer (i.e., a p-type layer) in the gate region so as to shift the threshold voltage. A recessed gate MISHEMT removes (i.e., recesses) a barrier layer of aluminum gallium nitride (AlGaN) to prevent the formation of the two-dimensional electron gas in a recessed gate region.

Unfortunately, the p-GaN HEMT and the recessed gate MISHEMT suffer from relatively high sheet resistance compared to that of a depletion mode GaN HEMT. Moreover, fabrication of the recessed gate MISHEMT may necessitate reactive ion etching (RIE) through at least ten nanometers of the requisite barrier layer (e.g., through an AlGaN layer of at least ten nanometers) in order to expose the GaN surface in the gate region. The prolonged exposure during the RIE can cause surface damage and lead to unreliable device behavior. For instance, the surface damage may lead to high leakage currents and to poor subthreshold slope characteristics.

A cascode solution typically requires integration of two or more dice (e.g., discrete devices) in one package. For instance, an AlGaN/GaN HEMT can be placed in one package with a low-voltage metal oxide semiconductor field effect transistor (MOSFET). The low-voltage MOSFET is typically a silicon low-voltage MOSFET. Unfortunately, packaging a silicon low-voltage MOSFET with an AlGaN/GaN HEMT can increase product and packaging cost. As this may also be undesirable, there is also a need for an alternative to the integrated silicon low-voltage MOSFET.

A double-channel semiconductor device is presented herein. The double-channel semiconductor device is a cascode solution integrating two semiconductor channels: a HEMT channel and a thin film transistor (TFT) channel. The HEMT channel can be an AlGaN/GaN HEMT channel and the TFT channel can be a polycrystalline silicon (polysilicon) TFT channel. The polysilicon TFT may advantageously operate in enhancement mode to realize an enhancement-mode cascode device.

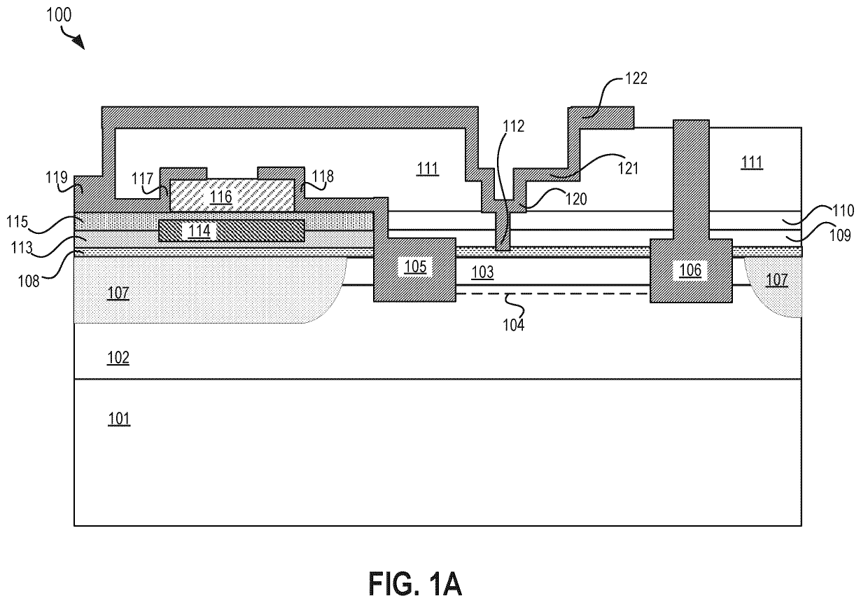

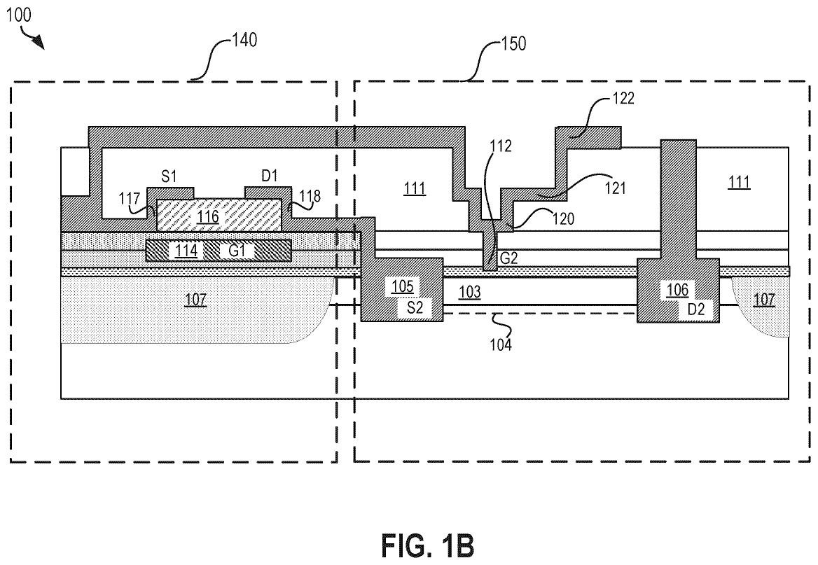

FIG. 1A illustrates a cross section of a double-channel semiconductor device 100 according to a first embodiment. The double-channel semiconductor device 100 includes a substrate 101, a GaN buffer layer 102, an AlGaN barrier layer 103, a two-dimensional electron gas (2DEG) 104, a HEMT source contact 105, a HEMT drain contact 106, implant isolation regions 107, a HEMT gate dielectric layer 108, a first passivation layer 109, a second passivation layer 110, a third passivation layer 111, a HEMT gate 112, a sacrificial dielectric region 113, a thin film transistor (TFT) gate 114, a TFT gate oxide 115, a TFT film 116, a TFT source contact 117, a TFT drain contact 118, a TFT source interconnect region 119, a first HEMT field plate 120, a second HEMT field plate 121, and a third HEMT field plate 122.

FIG. 1B illustrates the thin film transistor (TFT) 140 and the high electron mobility transistor (HEMT) 150 of the first embodiment. The thin film transistor (TFT) 140 comprises the sacrificial dielectric region 113, the thin film transistor (TFT) gate 114, the TFT gate oxide 115, the TFT film 116, the TFT source contact 117, the TFT drain contact 118, and the TFT source interconnect region 119. The high electron mobility transistor (HEMT) 150 comprises the GaN buffer layer 102, the AlGaN barrier layer 103, the two-dimensional electron gas (2DEG) 104, the HEMT source contact 105, the HEMT drain contact 106, and the HEMT gate dielectric layer 108. During operation, the 2DEG 104 may function as the HEMT channel, and the HEMT 150 can be a depletion mode HEMT 150.

The substrate 101 can comprise silicon, sapphire, and/or silicon carbide (SiC). The 2DEG 104 may form at or near the interface of the GaN buffer layer 102 and the AlGaN barrier layer 103. Additionally, the second passivation layer 110, the third passivation layer 111, the sacrificial dielectric region 113, the second HEMT field plate 121, and the third HEMT field plate 122 may be optional.

As illustrated the thin film transistor (TFT) 140 can be a bottom gate thin film transistor 140. According to the teachings herein, TFT film 116 may be a low temperature polysilicon (LTPS) TFT transistor. For instance, the TFT film 116 may be formed by depositing amorphous silicon and then by an anneal step to recrystallize the amorphous silicon. Alternatively, any TFT material may potentially be used as a TFT film 116. For instance, the TFT film 116 may be an organic TFT film 116 comprising indium gallium zinc oxide (IGZO). As described herein, during operation a channel may form within the TFT material (e.g., IGZO, LTPS), and the TFT 140 can be an enhancement mode TFT 140.

Also, as illustrated the TFT 140 may be electrically coupled (e.g., electrically coupled with interconnect) to the HEMT 150. For instance, the TFT drain contact 118 is electrically coupled to the HEMT source contact 105; and the TFT source contact 117 is electrically coupled to the HEMT gate 112.

Additionally, the TFT source contact 117 may be identified with a TFT source electrode S1. The TFT gate 114 may be identified with a TFT gate electrode G1; and the TFT drain contact 118 may be identified with a TFT drain electrode D1. Similarly, the HEMT source contact 105 may be identified with a HEMT source electrode S2. The HEMT gate 112 may be identified with a HEMT gate electrode G2; and the HEMT drain contact 106 may be identified with a HEMT drain electrode D2.

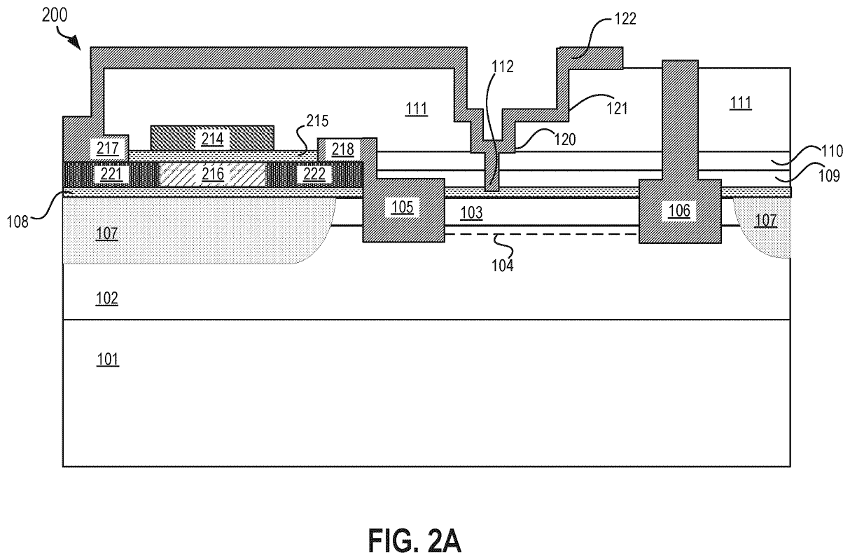

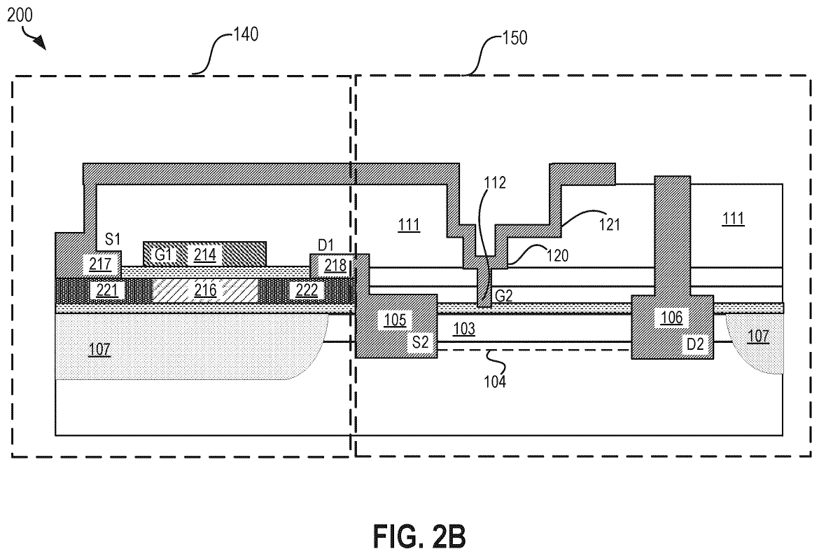

FIG. 2A illustrates a cross section of a double-channel semiconductor device 200 according to a second embodiment. Similar to the double-channel semiconductor device 100, double-channel semiconductor device 200 also includes a substrate 101, a GaN buffer layer 102, an AlGaN barrier layer 103, a two-dimensional electron gas (2DEG) 104, a HEMT source contact 105, a HEMT drain contact 106, implant isolation regions 107, a HEMT gate dielectric layer 108, a first passivation layer 109, a second passivation layer 110, a third passivation layer 111, a HEMT gate 112, a first HEMT field plate 120, a second HEMT field plate 121, and a third HEMT field plate 122.

In contrast to the double-channel semiconductor device 100, double-channel semiconductor device 200 includes thin film transistor (TFT) gate 214, a TFT gate oxide 215, a TFT film 216, a TFT source contact 217, and a TFT drain contact 218. Also, as illustrated the TFT film 216 includes a TFT source region 221 and a TFT drain region 222. The TFT source contact 217 may be in electrical contact (e.g., may form an ohmic contact) with the TFT source region 221; and the TFT drain contact 218 may be in electrical contact with the TFT drain region 222. In one embodiment the TFT source region 221 and the TFT drain region 222 may be formed within the TFT film 216 using ion implantation.

FIG. 2B illustrates the thin film transistor 140 and the high electron mobility transistor 150 of the second embodiment. As illustrated the thin film transistor (TFT) 140 can be a top gate thin film transistor 140. According to the teachings herein, TFT film 216 may be a low temperature polysilicon (LTPS) TFT transistor. For instance, the TFT film 216 may be formed by depositing amorphous silicon and then by an anneal step to recrystallize the amorphous silicon. Alternatively, any TFT material may potentially be used as a TFT film 216. For instance, the TFT film 216 may be an organic TFT film 216 comprising indium gallium zinc oxide (IGZO). As described herein, during operation a channel may form within the TFT material (e.g., IGZO, LTPS), and the TFT 140 can be an enhancement mode TFT 140.

Also, as illustrated the TFT 140 may be electrically coupled (e.g., electrically coupled with interconnect) to the HEMT 150. For instance, the TFT drain contact 218 is electrically coupled to the HEMT source contact 105; and the TFT source contact 217 is electrically coupled to the HEMT gate 112.

Additionally, the TFT source contact 217 may be identified with a TFT source electrode S1. The TFT gate 214 may be identified with a TFT gate electrode G1; and the TFT drain contact 218 may be identified with a TFT drain electrode D1.

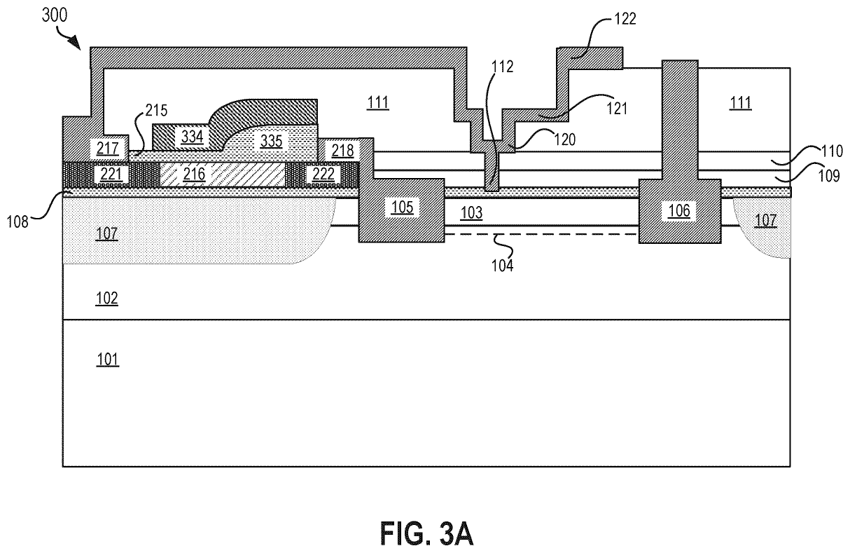

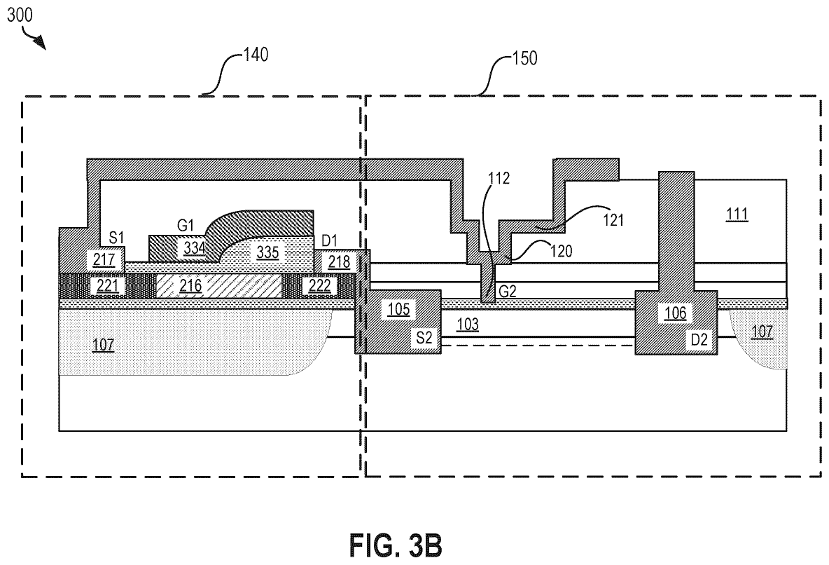

FIG. 3A illustrates a cross section of a double-channel semiconductor device 300 according to a third embodiment. The double-channel semiconductor device 300 is similar to double-channel semiconductor device 200, except the double-channel semiconductor device 300 includes both the TFT gate oxide 215 and a TFT field gate oxide 335 extending over the TFT film 216. Additionally, the double-channel semiconductor device 300 includes a TFT gate 334 which extends over both the TFT gate oxide 215 and the TFT field gate oxide 335. As described herein, the TFT field gate oxide 335 may reduce peak electric fields, thereby improving off-state blocking characteristics.

FIG. 3B illustrates the thin film transistor 140 and the high electron mobility transistor 150 of the third embodiment. As illustrated the thin film transistor (TFT) 140 can be a top gate thin film transistor 140. As discussed above the TFT field gate oxide 334 may reduce peak electric fields to improve off-state blocking characteristics. Accordingly, the TFT 140 of the third embodiment may also be referred to as a high voltage thin film transistor (HVTFT) 140. Additionally, the TFT gate 334 may be identified with a TFT gate electrode G1.

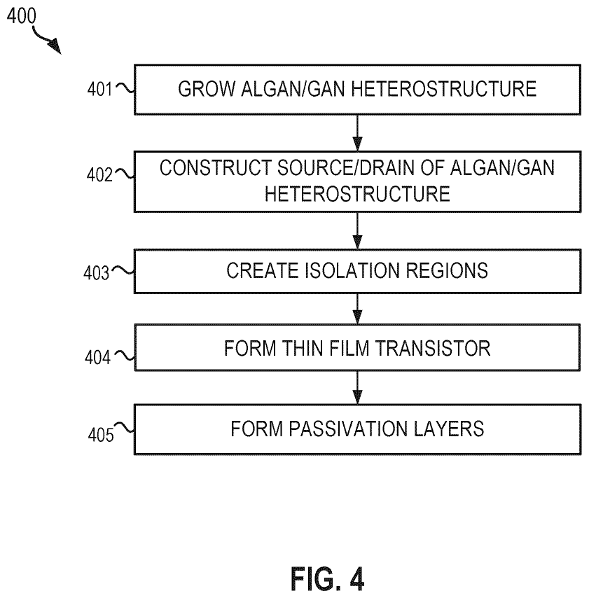

FIG. 4 illustrates process flow steps 401-405 for fabricating a double-channel semiconductor device 100 according to a first embodiment. Step 401 may correspond with growing an AlGaN/GaN heterostructure (i.e., AlGaN/GaN HEMT). In one embodiment the AlGaN/GaN heterostructure may be grown on a substrate 101 using a metal organic chemical vapor deposition (MOCVD) technique. Step 402 may correspond with constructing the source/drain of the AlGaN/GaN heterostructure. Ohmic contacts to the 2DEG 104 may be formed to construct the HEMT source contact 105 and the HEMT drain contact 106. Step 403 may correspond with creating isolation regions 107. During step 403 ion implantation and/or mesa structure etching may be performed to isolate the 2DEG 104 (i.e., to isolate the active region of the HEMT).

Step 404 may correspond with forming the TFT 140. On an implanted and/or etched-away portion of the AlGaN/GaN heterostructure, in the proximity of the HEMT source contact 105, a TFT structure (i.e., TFT 140) is formed. The TFT 140 may comprise a substrate insulation layer (e.g., substrate 101) such as silicon nitride (SiN), aluminum oxide (AlOx), silicon dioxide (SiO2), and/or a composite layer. Additionally, the TFT 140 may comprise a metallic gate, a gate dielectric layer (e.g., TFT gate oxide 115), an undoped polysilicon layer and/or an N-doped (N-type) polysilicon layer (e.g., TFT film 116). In an embodiment, a low- temperature (e.g., a temperature between four hundred and six hundred degrees Celsius) anneal recipe may be performed to recrystallize polysilicon and to improve mobilility. During step 404, ohmic contacts to the polysilicon (e.g., TFT source contact 117 and the TFT drain contact 118) may be formed. Additionally, the HEMT source contact 105 may be electrically coupled to the TFT drain contact 118.

Step 405 may correspond with forming passivation layers and/or metal interconnect layers. For instance, a plurality of of passivation layers and metallization layers may be formed as follows: a metal layer may be electrically coupled to the TFT source contact 117 through via holes in the passivation layer (e.g., the first passivation layer 109); and the TFT drain contact 118 may be electrically coupled with the HEMT source contact 105. Additionally, field plates (e.g., first, second, third HEMT field plates 120-122) may be formed during step 405.

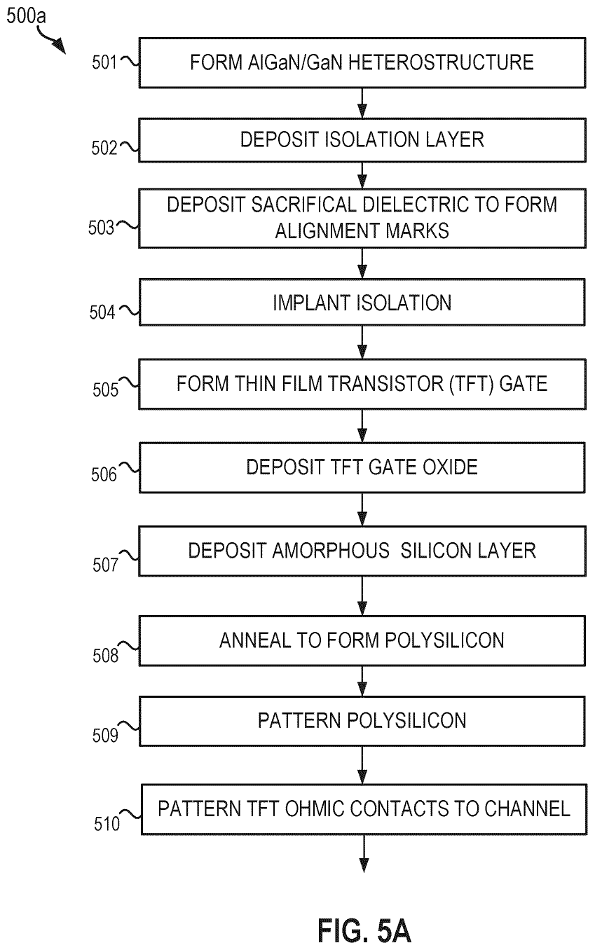

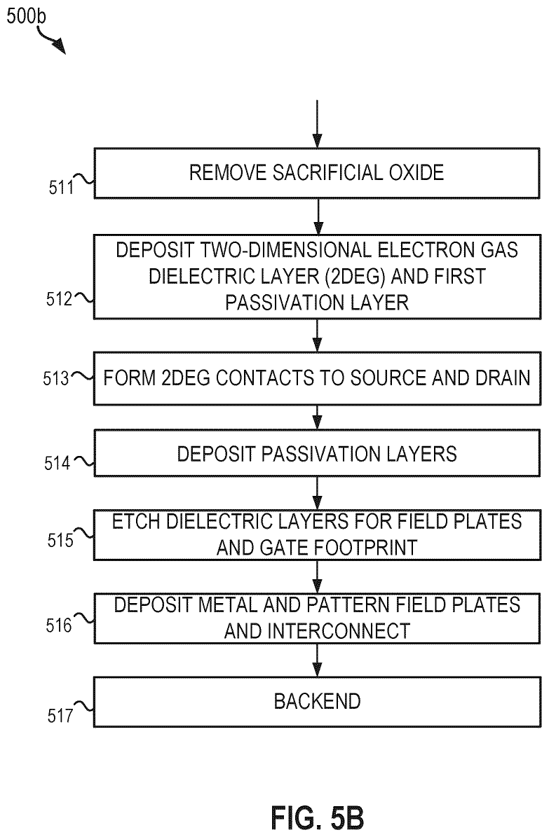

FIG. 5A illustrates process flow steps 501-510 for fabricating a double-channel semiconductor device 100 according to a second embodiment. Similar to step 401, step 501 may correspond with forming an AlGaN/GaN heterostructure (e.g., an AlGaN/GaN HEMT 150). Step 502 may correspond with depositing an isolation layer. During step 502 silicon nitride (SiN) or similar may be deposited on top of the the AlGaN/GaN heterostructure either with an in-situ (i.e., in the same reactor) approach using metal organic chemical vapor deposition or ex-situ approach using plasma enhanced chemical vapor deposition (PECVD) or low pressure chemical vapor deposition (LPCVD). The SiN may have a thickness between five and fifty nanometers (5-50 nm).

Step 503 may correspond with an optional step of depositing a sacrificial dielectric (e.g., sacrificial dielectric region 113) on the SiN. The sacrificial dielectric region 113 may comprise silicon oxide (SiOx) and may be patterned to form alignment marks. Step 504 may correspond with an implant recipe for creating an isolation region (e.g., isolation regions 107). Step 505 may correspond with forming a TFT gate (e.g., TFT gate 114). Step 506 may correspond with depositing a TFT gate oxide (e.g., TFT gate oxide 115).

Steps 507-509 may correspond with process steps to form a TFT channel (e.g., TFT film 116). For instance, step 507 may correspond with depositing an amorphous silicon layer. The amorphous silicon may also be doped (e.g., doped with an N-type or P-type impurity) during step 507. Step 508 may correspond with the subsequent anneal step to convert amorphous silicon into a polysilicon layer; and step 509 may correspond with patterning the polysilicon to form the TFT channel (e.g., TFT film 116). In one embodiment the anneal step 508 may be performed at a temperature between nine-hundred and nine-hundred fifty degrees Celsius (900-950 degrees C.).

Step 510 may correspond with patterning ohmic contacts (e.g., TFT source contact 117 and the TFT drain contact 118) to the TFT channel (e.g., TFT film 116).

FIG. 5B illustrates additional process flow steps 511-517 for fabricating a double-channel semiconductor device 100 according to the second embodiment. Step 511 may correspond with removing the sacrificial oxide (e.g., sacrificial dielectric region 113). Step 512 may correspond with depositing a 2DEG dielectric layer (e.g., HEMT gate dielectric layer 108) and a passivation layer (e.g., first passivation layer 109). Step 513 may correspond with forming source and drain contacts (e.g., HEMT source and drain contacts 105, 106). During step 513 HEMT source contact 105 may be electrically coupled to the TFT drain contact 118.

Step 514 may correspond with depositing additional, optional passivation layers (e.g., second and third passivation layers 110, 111). The optional passivation layers may comprise composite etch-stop layers to form trenches of fixed depth.

Step 515 may correspond with etching dielectric layers to form multiple filed plates and to define the HEMT gate footprint (e.g., HEMT gate 112). Step 516 may correspond with depositing metal and patterning field plates and interconnect. During step 516, the deposited metal layer may be patterned to connect the gate (e.g., HEMT gate 112) and/or field plates to the TFT source (e.g., TFT source interconnect region 119). Step 517 may correspond with additional backend processing including forming encapsulation layers and optional planarization and interconnects for the TFT source, HEMT drain, and TFT gate.

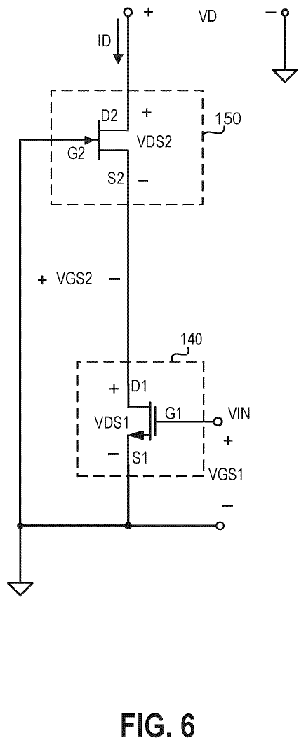

FIG. 6 illustrates a schematic diagram of a double-channel semiconductor device including a HEMT 150 and TFT 140 according to an embodiment. The schematic diagram illustrates a cascode connection whereby the HEMT source electrode S2 is electrically coupled to the TFT drain electrode D2. The HEMT 150 may be a depletion mode HEMT 150; accordingly the HEMT gate electrode G2 may be electrically connected with the TFT source electrode S1; and the HEMT 150 may operate in the “on-state” for values of HEMT gate-to-source voltage VGS2 greater than a depletion threshold. Additionally, the TFT 140 may be an enhancement mode TFT 140; accordingly the TFT gate electrode G1 may be used to control a drain current ID.

According to the teachings herein, the TFT gate-to-source voltage VGS1 may be applied such that the drain current ID is substantially reduced to zero when the TFT gate-to-source voltage VGS1 is reduced to zero. In the “off-state” the drain current ID may be substantially equal to zero; and the HEMT 150 may support a large HEMT drain-to-source voltage VDS2 between the HEMT drain electrode D2 and the HEMT source electrode S2. In the “off-state” the TFT 140 may support the HEMT gate-to-source voltage VGS2.

Additionally the TFT 140 may be tailored based upon the maximum “off-state” HEMT gate-to-source voltage VGS2. For instance, if the HEMT 150 has a depletion threshold of twenty volts, then the TFT 140 would be tailored to support at least twenty volts or greater to block the drain current ID. Accordingly, the TFT 140 may be fabricated to sustain a TFT drain-to-source voltage VDS1 at least equal to or greater than the depletion threshold. A large drain voltage VD may be supported in the off-state by virtue of the HEMT 150. For instance, in the “off-state” the drain voltage VD may block (i.e., support) eight-hundred twenty-five volts by virtue of the HEMT drain-to-source voltage VDS2 supporting eight-hundred volts plus the TFT drain-to-source voltage VDS1 supporting twenty-five volts.

Also according to the teachings herein, the TFT gate-to-source voltage VGS1 may be applied for large drain current ID when the TFT gate-to-source voltage VGS1 is greater than a positive threshold. For instance, the TFT 140 and the HEMT 150 may be fabricated according to a composite specific on-resistance and/or a maximum specified drain current ID.

### TCAD Device Simulations

Embodiments of the double-channel semiconductor device (e.g., double-channel semiconductor devices 100-300) may be simulated using technology computer aided design (TCAD). “TCAD simulations” or “TCAD device simulations” or “Synopsys Sentaurus TCAD device and process simulations” refers to simulations using SYNOPSYS® tools. (SYNOPSYS® and SYNOPSYS™ are trademarks of Synopsys, Inc., 690 East Middlefield Road, Mountain View, CA 94043) In the discussion below of device simulations, applications and device structures may refer to structures provided by and/or adopted from a TCAD database. For instance, one or more thin film device may be adapted from the application library found in the SYNOPSYS™ SolvNetPlus applications database.

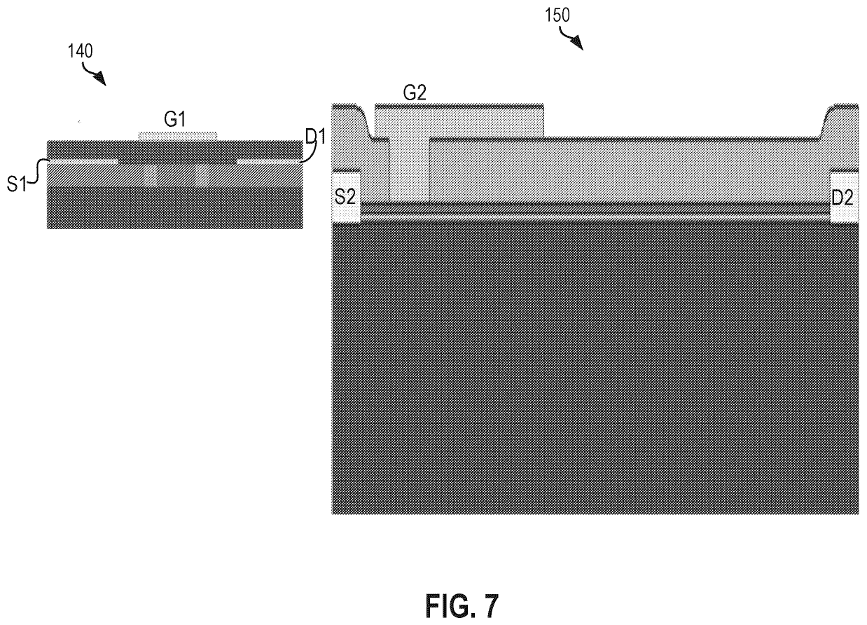

FIG. 7 illustrates a device structure realization of the thin film transistor (TFT) 140 and the high electron mobility transistor (HEMT) 150 according to a simulated embodiment. The simulated structure of the TFT 140 is adapted from the “Sentaurus Application Examples and Notes” titled “APAC 2018 Examples” under “Thin-Film Transistor Simulation for Active Matrix Flat Panel Displays.” Simulated device structures of the TFT 140 may be based, at least in part, on verification with experimental data. (see, e.g., Kimura, M. Behavior Analysis of an LDD Poly-Si TFT Using 2-D Device Simulation In: IEEE Trans. Electron Devices,. Vol.59, No. 3, March 2012, p. 705-709)

Simulated device structures of a HEMT 150 may also be adapted from a Sentaurus template or database. For instance, the HEMT 150 of FIG. 7 may be based upon a device structure derived from a GaN processing library for depletion mode high electron mobility transistors (HEMTs).

As discussed herein, Sentaurus mixed-mode simulations of the double-channel semiconductor device are based upon the electrical connections of electrodes according to the schematic of FIG. 6; accordingly, and as illustrated in FIG. 7, simulated electrodes are defined for the TFT source electrode S1, the TFT drain electrode D1, the TFT gate electrode G1, the HEMT source electrode S2, the HEMT drain electrode D2, and the HEMT gate electrode G2.

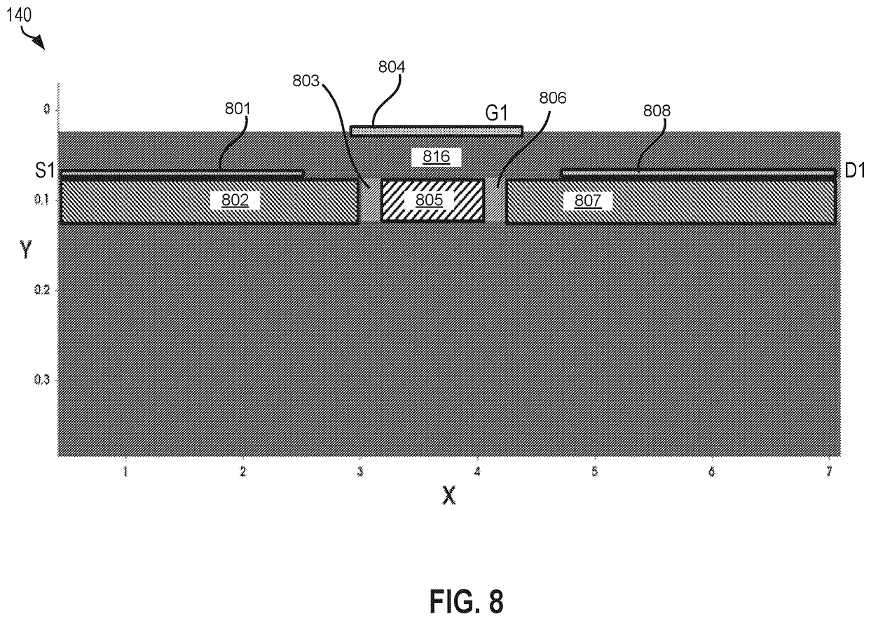

FIG. 8 illustrates a device structure of the TFT 140 according to a first double-channel embodiment. The TFT 140 device structure includes a TFT source electrode S1 801, a TFT gate electrode G1 804, and a TFT drain electrode D1 808. Additionally, the TFT 140 includes a gate oxide 816, a TFT thin film source region 802, a TFT thin film drain region 807, a TFT channel region 805, and TFT thin film lateral drain diffusion (LDD) extensions 803 and 806. Device depth is illustrated on the Y-axis in units of microns, and device width is shown on the X-axis in units of microns. An area scale factor may be equivalent to a perpendicular dimension along a Z-axis. For instance, if the area scale factor is one-thousand, then simulated quantities, such as device current, become scaled in units of amps per millimeter (A/mm).

The TFT 140 of FIG. 8 may be used in TCAD Sentaurus mixed-mode simulations of a double-channel semiconductor device. For instance, the TFT 140 of FIG. 8 may be used in simulations of double-channel semiconductor device 100 using a bottom-gate TFT 140; or it may be used in simulations of double-channel semiconductor device 200 using a top-gate TFT 140.

The TFT 140 may be based on a low-temperature polysilicon thin film (LTPS) process. Accordingly, the gate oxide 816 may be silicon dioxide (SiO2); thin TFT thin film source region 802, thin TFT thin film drain region 807, the TFT channel region 805, and TFT thin film lateral drain diffusion (LDD) extensions 803 and 806 may be modeled by an LTPS thin film model. In one embodiment TCAD “physics” models which are calibrated against empirical data. (see, e.g., Kimura, M. Behavior Analysis of an LDD Poly-Si TFT Using 2-D Device Simulation In: IEEE Trans. Electron Devices,. Vol.59, No. 3, March 2012, p. 705-709)

In one embodiment the TFT thin firm source region 802 and drain region 807 may be heavily doped N-type regions (e.g., doping of 2.0E19 inverse centimeters cubed). The TFT thin film LDD extensions may be doped N-type regions having a lighter doping level (e.g., doping of 1.0E17 inverse centimeters cubed). Additionally, the TFT channel region 805 may be lightly doped N-type or P-type material (e.g., doping of 2.0E15 inverse centimeters cubed). According to the teachings herein, the TFT channel region 805 may be doped such that a conductive channel region (e.g., N-type accumulation region and/or inversion region) forms under enhancement-mode conditions (e.g., a positive TFT gate-to-source voltage VGS1).

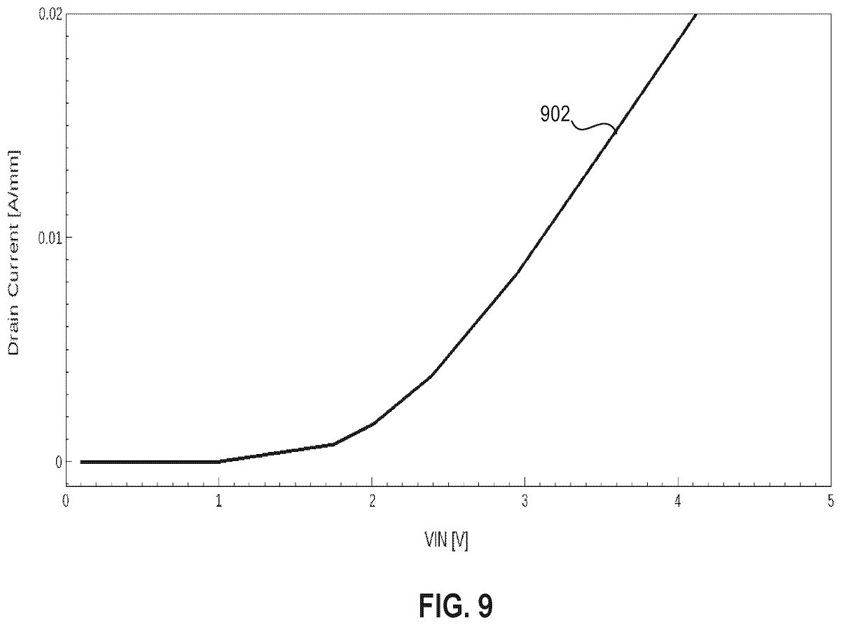

FIG. 9 illustrates a trace 902 of simulated drain current ID versus applied gate voltage VIN according to the first double-channel embodiment. Trace 902 illustrates enhancement-mode behavior whereby the drain current ID is substantially equal to zero for values of gate voltage VIN less than a TFT threshold. In the embodiment of FIG. 9 the HEMT 150 may be a GaN HEMT 150 such as that illustrated by HEMT 150 of FIG. 8; and the TFT 140 may correspond with TFT 140 of FIG. 8. In order to model the double-channel semiconductor device 100 and/or the double-channel device 200, the area scale factor of the simulated TFT 140 and the area scale factor of the simulated HEMT 150 are assigned equal values (e.g., an area scale factor of one thousand). Accordingly, the drain current ID has units of amps per millimeter (A/mm).

The TFT 150 may correspond with TFT 140 of FIG. 8; and the gate voltage VIN may be equal to the TFT gate-to-source voltage VGS1. Additionally, the HEMT 150 may have a threshold of approximately negative two volts (−2V); and the drain voltage VD may be equal to ten volts (10V).

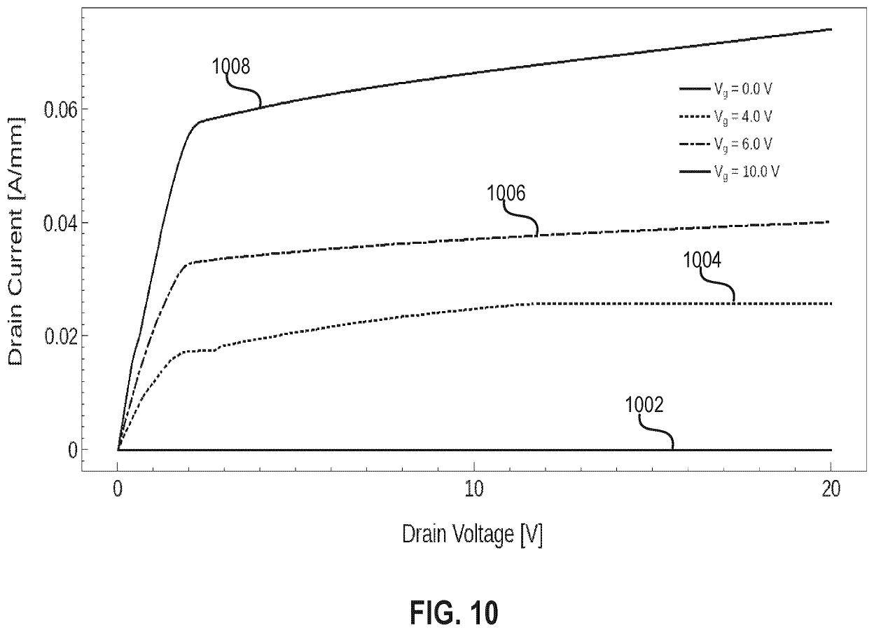

FIG. 10 illustrates simulated characteristic curves 1002, 1004, 1006, and 1008 according to the first double-channel embodiment. Characteristic curves 1002, 1004, 1006, and 1008 display drain current ID in amps per millimeter (A/mm) as a function of drain voltage VD. Characteristic curve 1002 may correspond with a gate voltage VIN equal to zero volts (0V). Characteristic curve 1004 may correspond with a gate voltage VIN equal to four volts (4V). Characteristic curve 1006 may correspond with a gate voltage VIN equal to six volts (6V); and characteristic curve 1008 may correspond with a gate voltage VIN equal to ten volts (10V).

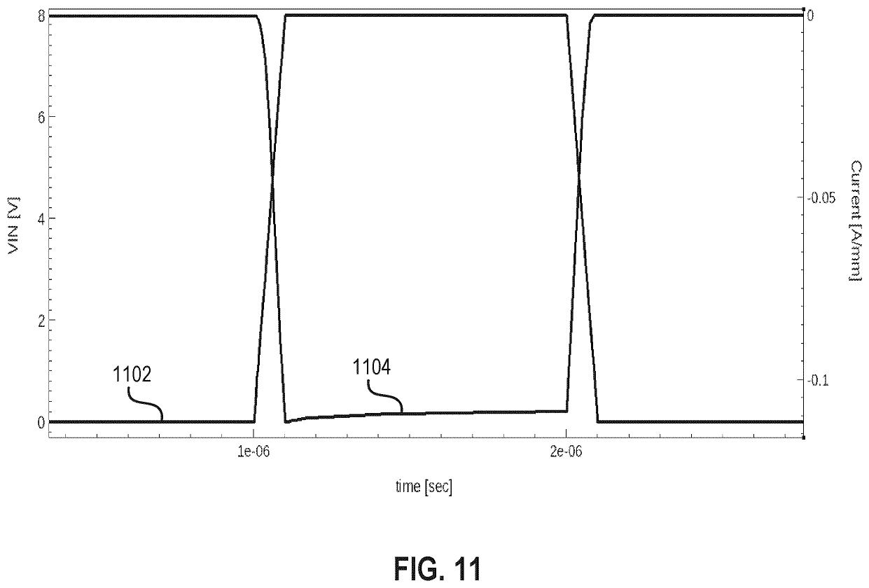

FIG. 11 illustrates simulated switching waveforms 1002 and 1004 according to the first double-channel embodiment. Switching waveforms 1002, 1004 are plotted as a function of time to illustrate switching behavior with a resistive load. Switching waveform 1002 may correspond with the gate voltage VIN; and switching waveform 1004 may correspond with drain current ID in units of amps per millimeter.

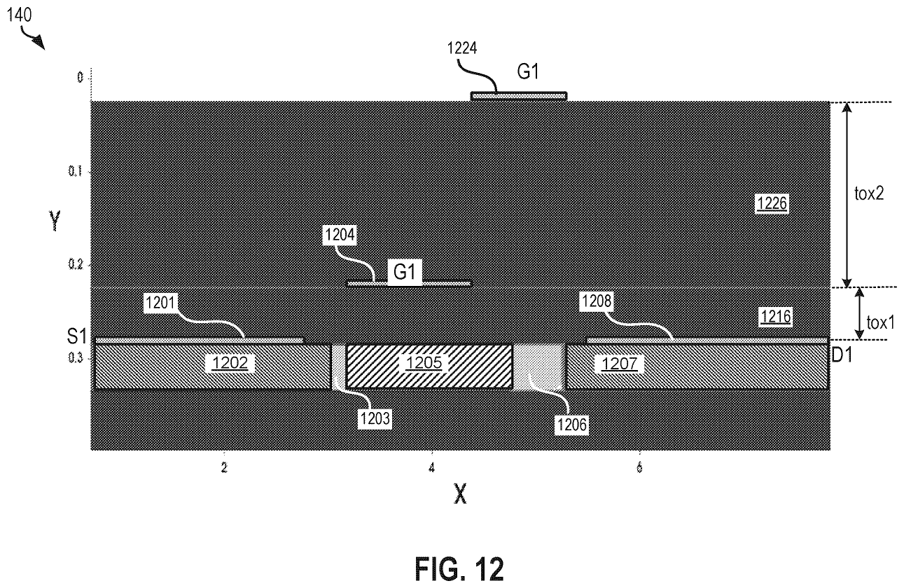

FIG. 12 illustrates a device structure of the TFT 140 according to a second double-channel embodiment. The TFT 140 of FIG. 12 may be used in TCAD Sentaurus mixed-mode simulations of a double-channel semiconductor device such as double-channel semiconductor device 300 using a high-voltage TFT 140.

The simulated materials of high-voltage TFT 140 in the second double-channel embodiment may be similar to that of TFT 140 in the first double-channel embodiment, except the TFT 140 of FIG. 12 may be patterned to support and/or block higher values of TFT drain-to-source voltage VDS1.

As illustrated the TFT 140 device structure includes a TFT source electrode S1 1201, a TFT gate electrode G1 1204, and a TFT drain electrode D1 1208. In order to simulate a field oxide region, the TFT 140 of FIG. 12 also includes an extension (e.g., a field plate) TFT gate electrode G1 1224. Additionally, the TFT 140 includes a gate oxide 1216, a field gate oxide 1226, a TFT thin film source region 1202; a TFT thin film drain region 1207, a TFT channel region 1205, and TFT thin film lateral drain diffusion (LDD) extensions 1203 and 1206.

Device depth is illustrated on the Y-axis in units of microns, and device width is shown on the X-axis in units of microns. An area scale factor may be equivalent to a perpendicular dimension along a Z-axis. For instance, if the area scale factor is one-thousand, then simulated quantities, such as device current, become scaled in units of amps per millimeter (A/mm).

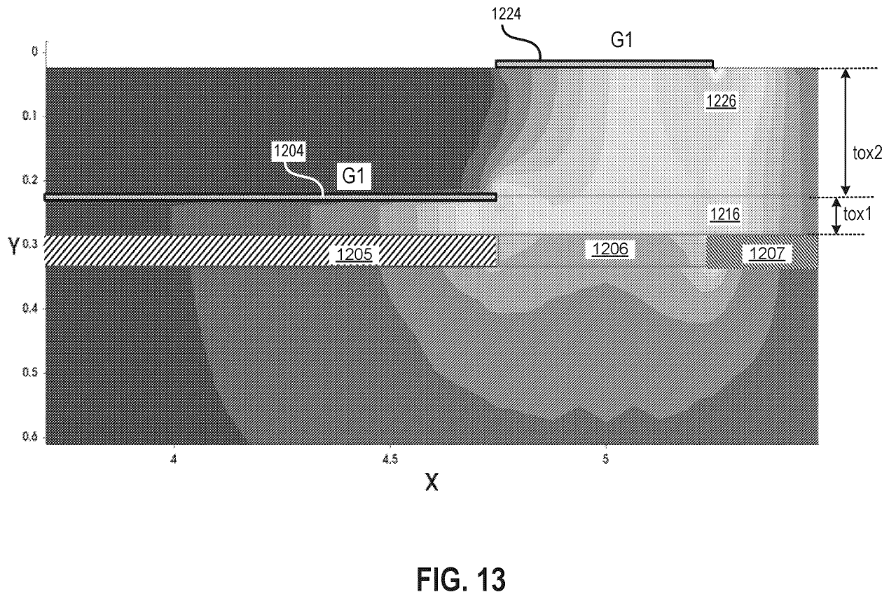

FIG. 13 illustrates simulated electric field of the TFT 140 according to the second double-channel embodiment. As illustrated the electric field terminates at the field plate extension (e.g., a field plate) TFT gate electrode G1 1224 through the field gate oxide 1226. As illustrated the field gate oxide 1226 has a larger thickness tox2 than the gate oxide 1216. Thus, as discussed below, the peak electric field in the second double-channel embodiment may be reduced. In turn, the second double-channel embodiment may be used with a HEMT 150 having a larger magnitude (i.e., a more negative) threshold voltage.

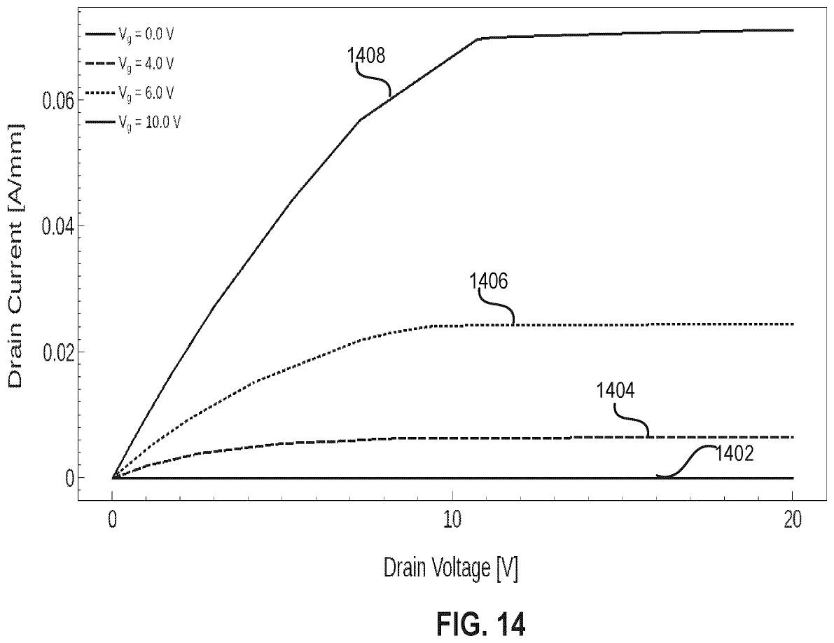

FIG. 14 illustrates simulated characteristic curves 1402, 1404, 1406, and 1408 according to the second double-channel embodiment. Characteristic curves 1402, 1404, 1406, and 1408 display drain current ID in amps per millimeter (A/mm) as a function of drain voltage VD. Characteristic curve 1402 may correspond with a gate voltage VIN equal to zero volts (0V).

Characteristic curve 1402 may correspond with a gate voltage VIN equal to four volts (4V). Characteristic curve 1406 may correspond with a gate voltage VIN equal to six volts (6V); and characteristic curve 1408 may correspond with a gate voltage VIN equal to ten volts (10V).

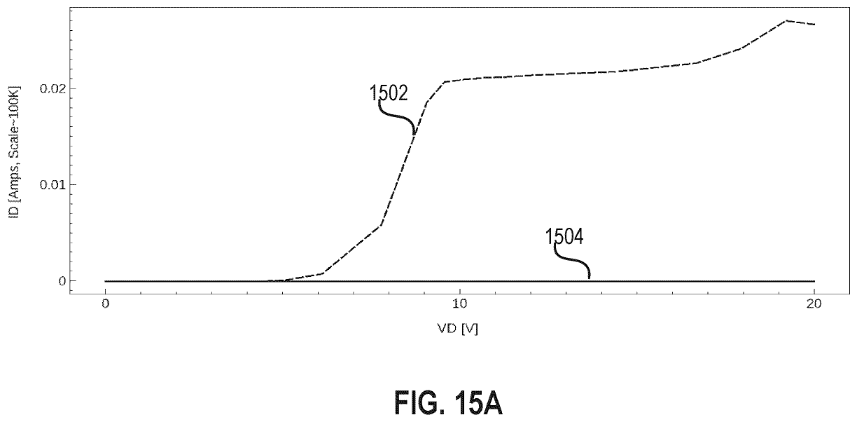

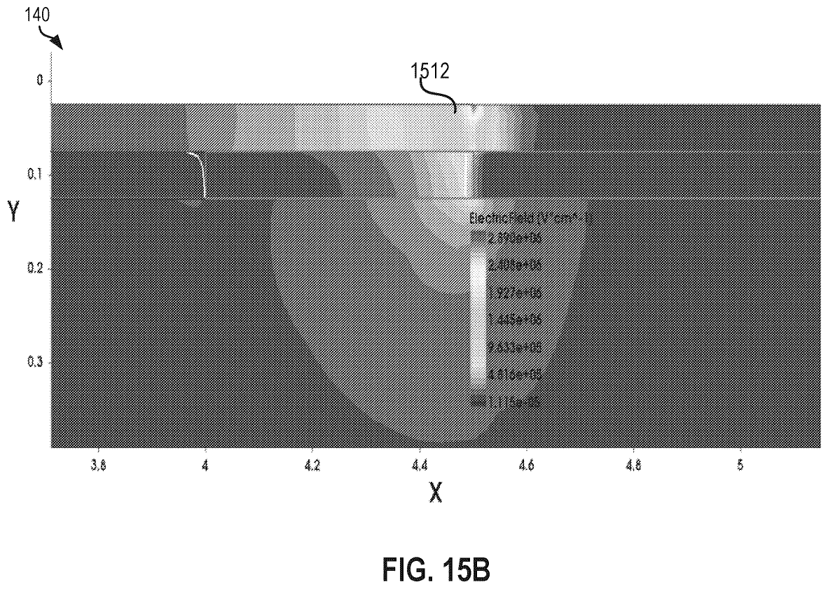

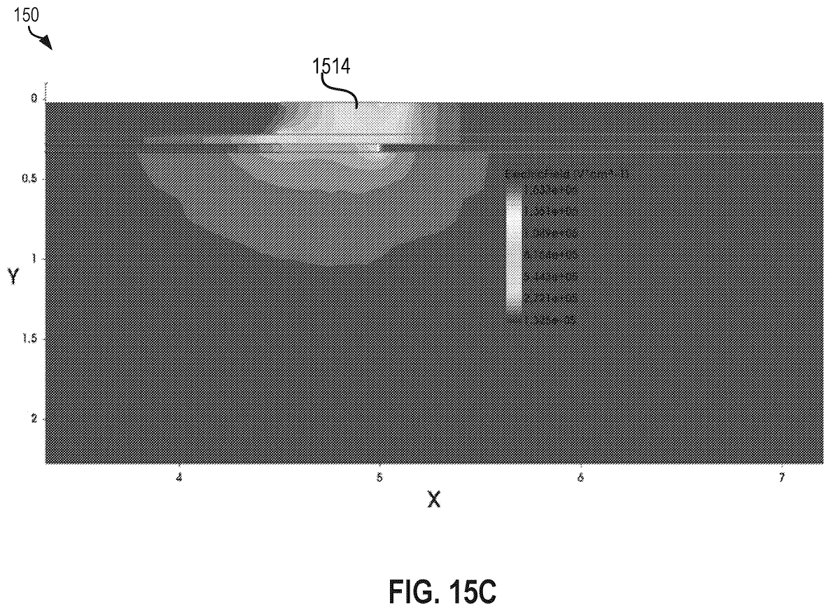

FIG. 15A compares traces 1502, 1504 of simulated off-state current according to thin film transistor embodiments. Both traces 1502 and 1504 plot drain current ID as a function of drain voltage VD. Trace 1502 may correspond with a TCAD simulation of a double-channel semiconductor device using a HEMT 150 having a depletion threshold of approximately negative twelve volts (−12V) and using the TFT 140 of FIG. 8. The area scale factor of both the HEMT 150 and TFT 140 has been increased to equal one-hundred thousand (100K).

Trace 1502 may correspond with a simulation of a double-channel semiconductor device using a HEMT 150 having a depletion threshold of approximately negative twelve volts (−12V) and using TFT 140 of FIG. 8. The trace 1504 may correspond with a simulation of a double-channel semiconductor device using a HEMT 150 having a depletion threshold of approximately negative twelve volts (−12V) but using the high voltage TFT 140 of FIG. 12. In comparison trace 1504 shows the high voltage TFT 140 of FIG. 12 provides superior blocking (i.e., exhibits lower leakage) in a double-channel semiconductor device.

For comparison FIG. 15B illustrates simulated electric field 1512 of the TFT 140 according to the embodiment of trace 1502; and FIG. 15C illustrates simulated electric field 1514 of TFT 140 according to the embodiment of trace 1504. The simulated electric fields 1512 and 1514 both correspond to a condition whereby the drain voltage VD equals to twenty volts. As illustrated the electric field 1514 of the high voltage TFT 140 advantageously has a lower peak value (e.g., approximately 1.6E-6 volts per centimeter) than that of electric field 1512 (e.g., approximately 2.9E-6 volts per centimeter).

The above description of illustrated examples of the present disclosure, including what is described in the Abstract, are not intended to be exhaustive or to be limitation to the precise forms disclosed. While specific embodiments of, and fabrication steps of a double-channel semiconductor device are described herein for illustrative purposes, various equivalent modifications are possible without departing from the broader spirit and scope of the present disclosure. Indeed, it is appreciated that the specific example process recipes (i.e., process steps) and device cross sections are provided for explanation purposes and other process recipes with greater or fewer steps may also be employed in other embodiments and examples in accordance with the teachings herein.

1. A semiconductor device comprising:
a high electron mobility transistor (HEMT);
a thin film transistor (TFT) electrically coupled in cascode with the HEMT and comprising:
a TFT thin film source region;
a TFT thin film drain region; and
a TFT channel region between the TFT thin film source region and the TFT thin film drain region, the TFT channel region doped such that an accumulation region forms under enhancement mode conditions.

2. The semiconductor device of claim 1, wherein the HEMT comprises Gallium Nitride (GaN).

3. The semiconductor device of claim 1, wherein the TFT comprises silicon.

4. The semiconductor device of claim 1, wherein the TFT comprises amorphous Silicon (a-Si).

5. The semiconductor device of claim 1, wherein the TFT comprises polycrystalline Silicon (polysilicon).

6. The semiconductor device of claim 5, wherein the TFT is a low temperature polysilicon (LTPS) TFT.

7. The semiconductor device of claim 1, wherein the TFT comprises Indium.

8. The semiconductor device of claim 7, wherein the TFT is an Indium Gallium Zinc Oxide (IGZO) TFT.

9. The semiconductor device of claim 1, wherein the TFT comprises a gate oxide and a field gate oxide.

10. The semiconductor device of claim 9, wherein a thickness of the field gate oxide is greater than a thickness of the gate oxide.

11. A method of fabricating a dual channel semiconductor device comprising:
growing a heterostructure device;
constructing a source region and a drain region in the heterostructure device;
creating an isolation region; and
forming a thin film transistor (TFT), wherein forming the TFT comprises:
doping a TFT channel region such that an accumulation region forms under enhancement mode conditions.

12. The method of claim 11, wherein growing the heterostructure device comprises:
depositing a layer of Gallium Nitride (GaN) in a chemical vapor deposition (CVD) reactor; and
depositing a layer of Aluminum Gallium Nitride (AlGaN) in the CVD reactor.

13. The method of claim 12, wherein constructing the source region and the drain region in the heterostructure device comprises:
forming an ohmic contact to a two-dimensional electron gas (2DEG) of the heterostructure device.

14. The method of claim 13, wherein the ohmic contact is a source ohmic contact.

15. The method of claim 13, wherein the ohmic contact is a drain ohmic contact.

16. The method of claim 13, wherein creating the isolation region comprises:
isolating an active region of the 2DEG.

17. The method of claim 16, wherein isolating the active region of the 2DEG comprises:
etching a mesa structure.

18. The method of claim 12, wherein forming the TFT comprises:
forming a polysilicon TFT adjacent to the source region.

19. The method of claim 18, wherein forming the polysilicon TFT comprises:
annealing the polysilicon TFT at a temperature less than six-hundred degrees Celsius.

20. The method of claim 18, wherein forming the polysilicon TFT comprises:
forming an ohmic contact in the polysilicon TFT.

21. The method of claim 20 wherein forming the polysilicon TFT comprises:
electrically coupling the ohmic contact to the source region in the heterostructure device.
